(19) United States
(12) Patent Application Publication
(10) Pub. No.: US 2013/0126219 A1
(43) Pub. Date: May 23, 2013

(54) MULTI-PLY CIRCUIT BOARD WITH FIBER BUNDLES

(71) Applicant: Samsung Electronics Co., Ltd., Suwon-si (KR)

(72) Inventors: Pyoungwan Kim, Suwon-si (KR); Taeeun Kim, Hwaseong-si (KR)

(73) Assignee: SAMSUNG ELECTRONICS CO., LTD., Suwon-si (KR)

(21) Appl. No.: 13/657,253

(22) Filed: Oct. 22, 2012

(30) Foreign Application Priority Data
Nov. 22, 2011 (KR) 10-2011-0122107

(51) Int. Cl. H05K 1/02; B32B 3/10; H05K 1/11

(52) U.S. Cl. 174/256; 428/196; 428/113

(57) ABSTRACT

Provided is a circuit board that includes a first layer on which circuit patterns are disposed, a second layer opposite to the first layer and on which external terminals are disposed, and a core portion disposed between the first and second layers and including a first ply and a second ply which are stacked. The first ply includes a first fiber bundle extending in a first direction, a second fiber bundle extending in a second direction, and a non-fiber area defined by the first and second fiber bundles. The second ply includes a first fiber bundle extending in a third direction and a second fiber bundle extending in a fourth direction. The first and second fiber bundles of the second ply overlap at least part of the non-fiber area of the first ply.

### CROSS-REFERENCE TO RELATED APPLICATIONS

This United States non-provisional patent application claims priority under 35 USC §119 to Korean Patent Application No. 10-2011-0122107, filed on Nov. 22, 2011, the entirety of which is hereby incorporated by reference.

### FIELD OF THE INVENTION

The inventive concepts described herein generally relate to circuit boards and, more particularly, to a circuit board for use in a semiconductor package.

### BACKGROUND OF THE INVENTION

As electronic products tend to be more and more miniature in size and higher in performance, semiconductor package continue to decrease in size. A semiconductor package may include one or more “circuit boards.” Each circuit board can comprise a plurality of semiconductor devices, each manufactured by the patterned diffusion of trace elements into the layer of a thin substrate of semiconductor material. Additional materials can be deposited and patterned to form interconnections between semiconductor devices.

In particular, an approach to decreasing the size of a semiconductor package is to attempt to decrease the thicknesses of the circuit boards used to make such semiconductor packages. Various studies on circuit boards have been performed in an attempt to achieve such decreases in the thicknesses, but reliable advancement in this area has been challenging.

### SUMMARY OF THE INVENTION

According to one aspect of the inventive concept, provided is a circuit board, comprising a first layer, a second layer stacked on the first layer, a core potion disposed between the first and second layers. The core potion comprising a plurality of plies, where each ply is formed of interwoven fibers. A first ply defines a first non-fiber area that is at least partially overlapped by fibers of at least one other ply.

According to various embodiments, a second ply can define a second non-fiber area that is at least partially covered by fibers of the first ply.

According to various embodiments, the plurality of plies can include the first ply and a second ply. The first ply can comprise a first fiber bundle of the first ply having fibers extending in a first direction interwoven with a second fiber bundle of the first ply having fibers extending in a second direction. And the second ply can comprise a first fiber bundle of the second ply having fibers extending in a third direction interwoven with a second fiber bundle of the second ply having fibers extending in a second direction.

According to various embodiments, each fiber in the first fiber bundle of the first ply can have a first thickness, and each fiber of the second fiber bundle of the first ply can have a second thickness substantially greater than the first thickness.

According to various embodiments, each fiber of the first fiber bundle of the second ply can have a third thickness, and each fiber of the second fiber bundle of the second ply can habe a fourth thickness substantially greater than the first thickness.

According to various embodiments, the first thickness can be substantially equal to the third thickness and the second thickness can be substantially equal to the fourth thickness.

According to various embodiments, the fibers of the first fiber bundle of the first ply can be disposed at an angle in a range of about 10 to about 90 degrees to the fibers of the second fiber bundle of the second ply, and the fibers of the second fiber bundle of the first ply can be disposed at an angle in a range of about 10 to about 90 degrees to the fibers of the second fiber bundle of the second ply.

According to another aspect of the inventive concept, provided is a circuit board that includes a first layer on which circuit patterns are disposed, a second layer opposite to the first layer and on which external terminals are disposed, and a core portion disposed between the first and second layers and including a first ply stacked on a second ply. The first ply may include a first fiber bundle extending in a first direction and a second fiber bundle extending in a second direction, with the first and second fiber bundles defining a non-fiber area of the first ply. The second ply may include a first fiber bundle extending in a third direction and a second fiber bundle extending in a fourth direction. The first and second fiber bundles of the second ply may overlap at least part of the non-fiber area of the first ply.

According to various embodiments, the first and second fiber bundles of the second ply may define a non-overlap area of the second ply, and the first and second fiber bundles of the first ply may overlap at least part of the non-fiber area of the second ply.

According to various embodiments, each fiber in the first fiber bundle of the first ply may have a first thickness, and each fiber of the second fiber bundle of the first ply may have a second thickness substantially greater than the first thickness.

According to various embodiments, each fiber in the first fiber bundle of the second ply may have a first thickness, and each fiber in the second fiber bundle of the second ply may have a second thickness substantially greater than the first thickness.

According to various embodiments, the third direction may be substantially identical to the first direction, and the fourth direction may be substantially identical to the second direction.

According to various embodiments, a thickness of each fiber of the first fiber bundle of the first ply may be substantially smaller than the thickness of each fiber of the first fiber bundle of the second ply, and a thickness of each fiber of the second fiber bundle of the first ply may be substantially greater than the thickness of each fiber of the second fiber bundle of the second ply.

According to various embodiments, a thickness of each fiber of the first fiber bundle of the first ply may be substantially equal to the thickness of each fiber of the first fiber bundle of the second ply, and a thickness of each fiber of the second fiber bundle of the first ply may be substantially equal to the thickness of each fiber of the second fiber bundle of the second ply. The fibers of first fiber bundle of the second ply may be disposed between adjacent fibers of the first fiber bundle of the first ply.

According to various embodiments, fibers in the second fiber bundle of the second ply may be disposed between adjacent fibers of the second fiber bundle of the first ply.

According to various embodiments, the first and second fiber bundles of the first ply may be disposed to vertically intersect each other in a woven fabric structure, and the first and second fiber bundles of the second ply may be disposed to vertically intersect each other in a woven fabric structure.

According to various embodiments, the first fiber bundle of the first ply may be disposed at an angle in a range of about 10 to about 90 degrees to the second fiber bundle of the second ply, and the second fiber bundle of the first ply may be disposed at an angle in a range of about 10 to about 90 degrees to the second fiber bundle of the second ply.

According to various embodiments, the circuit board may further include a via penetrating the first layer, the core portion, and the second layer.

According to another aspect of the inventive concept, provided is a method of making a circuit board. The method comprises forming a first ply and a second ply, including forming each ply by interweaving fibers, wherein the at least one of the first and second plies defines a non-fiber area, forming a core portion by stacking the first and second plies, including arranging the first ply with respect to the second ply to at least partially overlap the non-fiber area, and disposing the core portion between a first layer and a second layer.

According to various embodiments, the method can further comprise arranging the first ply at an angle with respect to the second ply to at least partially overlap the non-fiber area.

According to various embodiments, the method can further comprise laterally offsetting the first ply with respect to the second ply to at least partially overlap the non-fiber area.

According to various embodiments, the method can further comprise forming a circuit pattern on the first surface, forming an external terminal on the second surface, and

forming a via from the circuit pattern of the first surface, through the core portion, to the external terminal.

### BRIEF DESCRIPTION OF THE DRAWINGS

The inventive concept will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the inventive concept.

FIG. 1 is an exploded perspective view of an embodiment of a circuit board according to an aspect of the inventive concept.

FIG. 2 is a cross-sectional view of an embodiment of a circuit board taken along a line I-I′ in FIG. 1.

FIG. 3A is a top plan view of an embodiment of a first ply shown in FIG. 1.

FIG. 3B is a top plan view of an embodiment of a second ply shown in FIG. 1.

FIG. 3C is a top plan view of an embodiment of a core portion shown in FIG. 1.

FIG. 4A is a cross-sectional view of an embodiment of a circuit board according to another aspect of the inventive concept.

FIG. 4B is a top plan view of the circuit board in FIG. 4A.

FIG. 5 is a flowchart illustrating an embodiment of a method of manufacturing a circuit board according to an aspect of the inventive concept.

FIG. 6A is a block diagram of an embodiment of a memory card to which a memory device can be applied, according to aspects of the inventive concept.

FIG. 6B is a block diagram of an embodiment of a system including a memory device, according to aspects of the inventive concept.

### DETAILED DESCRIPTION

The advantages and features of the inventive concept and methods of achieving them will be apparent from the exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose examples in accordance with the inventive concept and to let those skilled in the art understand the nature of the inventive concept.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

Exemplary embodiments of the invention will be described below with reference to various views, which are exemplary drawings that demonstrate aspects of the invention. The items, layers, structures and the like depicted in the exemplary drawings may be modified by manufacturing techniques and/or tolerances. Accordingly, the exemplary embodiments are not limited to specific configurations shown in the drawings, and include modifications based on the method of manufacturing the semiconductor device, for example.

Though terms like a first, a second, and a third are used to describe various elements in various embodiments, the elements are not limited to these terms. These terms are used only to tell one element from another element, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

The terms used in the present specification are used to describe a particular embodiment and are not used to limit the present invention. As in the present specification, a singular form may include a plural form unless the singular form definitely indicated otherwise in the context. Also, in the present specification, the terms “comprise” and/or “comprising” specify existence of shapes, numbers, steps, operations, members, elements, and/or groups thereof, which are referred to, and do not exclude existence or addition of one or more different shapes, numbers, operations, members, elements, and/or groups thereof.

Exemplary embodiments in accordance with the inventive concept will now be described more fully hereinafter with reference to the accompanying drawings.

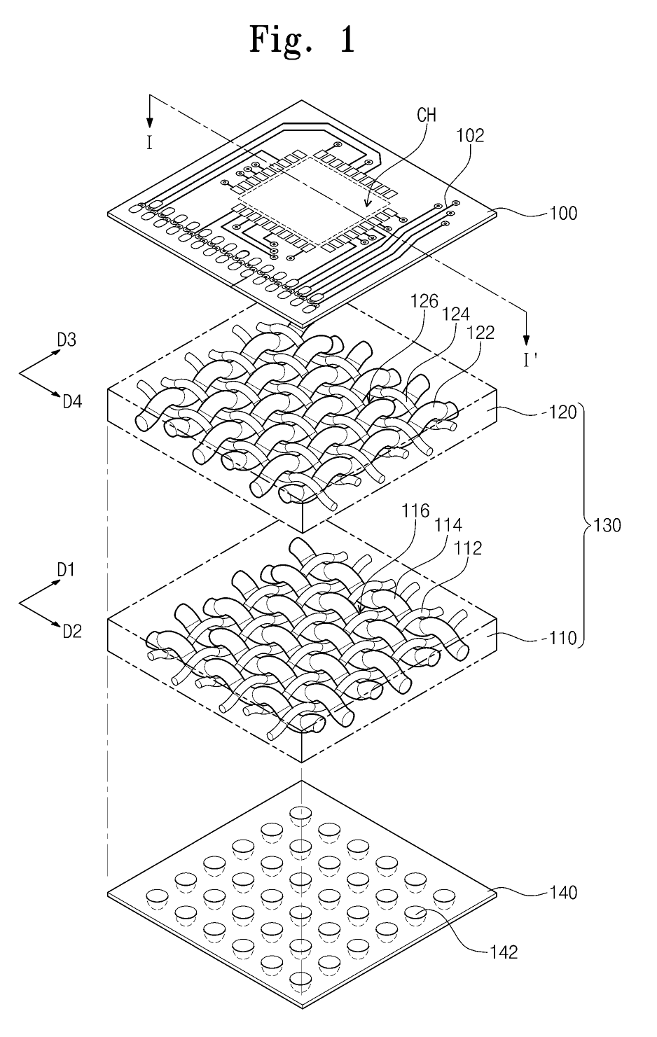

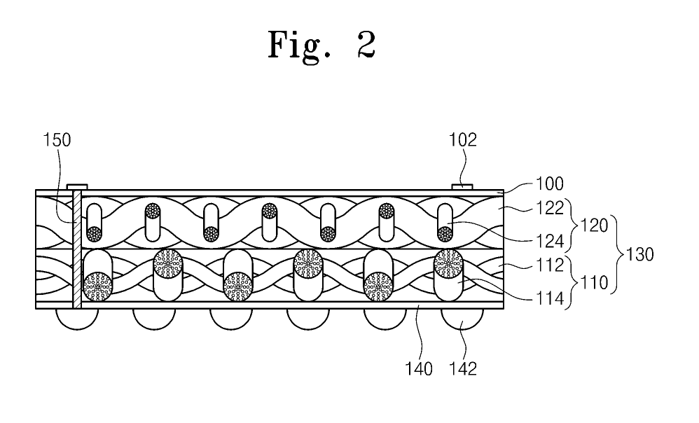

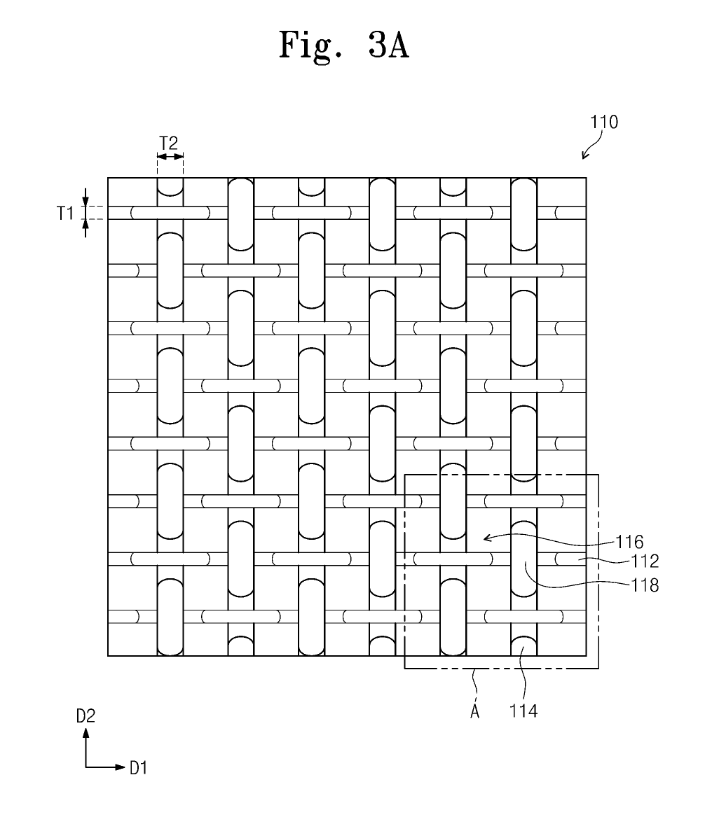

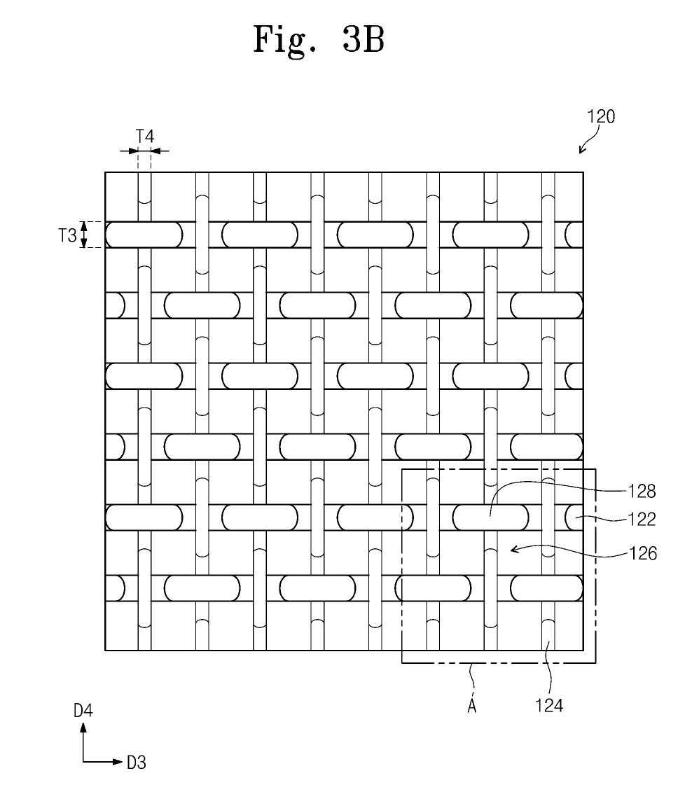

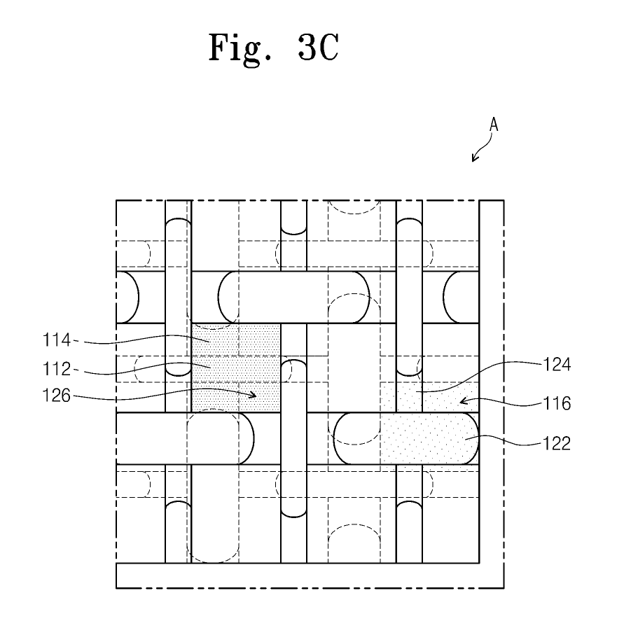

FIG. 1 is an exploded perspective view of an embodiment of a circuit board according to an aspect of the inventive concept, and FIG. 2 is a cross-sectional view of a circuit board taken along a line I-I′ in FIG. 1. FIG. 3A is a top plan view of an embodiment of a first ply shown in FIG. 1 and FIG. 3B is a top plan view of an embodiment of a second ply shown in FIG. 1. FIG. 3C is a top plan view of an embodiment of a core portion shown in FIG. 1. More specifically, FIG. 3C is a top plan view in which the first ply in FIG. 3A and the second ply in FIG. 3B are stacked to form the core portion and the core portion is cut along lines forming a region “A”.

Referring to FIGS. 1 and 2, the circuit board may include a first layer 100, a second layer 140 opposite to the first layer 100, and a core portion 130 disposed between the first and second layers 100 and 140.

A plurality of circuit patterns 102 may be printed on the first layer 100. The circuit patterns 102 may include a metal, such as copper. Although not shown in detail, a protection layer may be formed on the first layer 100 to protect the circuit patterns 102. The protection layer may be a solder resist (SR), as an example. A chip area CH may be formed on the first layer 100. At least one semiconductor chip is mounted in the chip area CH.

The second layer 140 may be disposed opposite to the first layer 100 and spaced apart from the first layer 100. One or more external terminals 142 may be disposed on the second layer 140. The external terminals 142 may be electrically connected to the circuit patterns 102 of the first layer 100 through at least one via 150 penetrating the core portion 130, as is shown in FIG. 2.

Referring to FIGS. 1, 2, 3A, 3B, and 3C, the core portion 130 may include a first ply 110 and a second ply 120. The first and second plies 110 and 120 may be horizontally disposed and vertically stacked, one on top of another.

The first ply 110 may include a first fiber bundle 112 extending in a first direction D1 and a second fiber bundle 114 extending in a second direction D2. The first and second directions D1 and D2 may be substantially perpendicular to each other. Each of the first and second fiber bundles 112 and 114 of the second ply includes a number of fibers. In the demonstrated embodiment, fibers in the first fiber bundle 112 of the first ply 110 are spaced apart at regular intervals to be disposed parallel to each other in the second direction D2. Also, fibers in the second fiber bundle 114 of the first ply 110 may be spaced apart at regular intervals to be disposed parallel to each other in the first direction Dl. The first and second fiber bundles 112 and 114 of the first ply 110 may vertically intersect each other in a woven fabric structure. In other embodiments, the first fiber bundle 112, the second fiber bundle 114, or both need not be spaced apart at regular intervals.

Each of the first and second fiber bundles 112 and 114 of the first ply 110 includes a number of fibers that may be substantially identical in thickness and shape. That is, the fibers in the first fiber bundle 112 may be substantially identical in thickness and shape and the fibers in the second fiber bundle 114 may be substantially identical in thickness and shape, even though the fibers in the second fiber bundle 114 may have a different thickness, shape, or both of the fibers in the first fiber bundle 112. In yet other embodiment, fibers in the first bundle 112 may have different thicknesses and shapes, fibers in the second bundle 114 may have different thicknesses and shapes, or both.

According to one embodiment of the inventive concept, each of the fibers in the first fiber bundle 112 of the first ply 110 may have a first thickness T1 and serve as a weft yarn in the woven fabric structure. Each of the fibers in the second fiber bundle 114 of the first ply 110 may have a second thickness T2 greater than the first thickness T1 and serve as a warp yarn in the woven fabric structure.

The first ply 110 may include a non-fiber area 116 defined by the first and second fiber bundles 112 and 114 of the first ply 110. The non-fiber area 116 of the first ply 110 may be disposed adjacent to an intersection area 118 in which the first and second fiber bundles 112 and 114 of the first ply 110 intersect each other. The non-fiber area 116 may take the form of a gap between fibers of the first and second fiber bundles 112 and 114.

The second ply 120 may include a first fiber bundle 122 extending in a third direction D3 and a second fiber bundle 124 extending in a fourth direction D4. The third and fourth directions D3 and D4 may be substantially perpendicular to each other. According to one embodiment of the inventive concept, the third direction D3 may be substantially identical to the first direction D1, and the fourth direction D4 may be substantially identical to the second direction D2.

Each of the first and second fiber bundles 122 and 124 of the second ply includes a number of fibers. In the demonstrated embodiment, fibers in the first fiber bundle 122 of the second ply 120 are spaced at regular intervals to be disposed parallel to each other in the second direction D2. Also, fibers in the second fiber bundle 124 of the second ply 120 may be spaced at regular intervals to be disposed parallel to each other in the first direction Dl. The first and second fiber bundles 122 and 124 of the second ply 120 may vertically intersect each other in a woven fabric structure. In other embodiments, the first fiber bundle 122, the second fiber bundle 124, or both need not be spaced apart at regular intervals.

Fibers in each of the first and second fiber bundles 122 and 124 of the second ply may be identical in thickness and shape. That is, the fibers in the first fiber bundle 122 may be substantially identical in thickness and shape and the fibers in the second fiber bundle 124 may be substantially identical in thickness and shape, even though the fibers in the second fiber bundle 124 may have a different thickness, shape, or both of the fibers in the first fiber bundle 122. In yet other embodiment, fibers in the first bundle 122 may have different thicknesses and shapes, fibers in the second bundle 124 may have different thicknesses and shapes, or both.

According to one embodiment of the inventive concept, each of the first fiber bundles 122 of the second ply 120 may have a third thickness T3, and each of the second fiber bundles 124 of the second ply 120 may have a fourth thickness T4. The third thickness T3 may be substantially equal to the second thickness T2, and the fourth thickness T4 may be substantially equal to the first thickness T1.

The second ply 120 may include a non-fiber area 126 defined by the first and second fiber bundles 122 and 124 of the second ply 120. The non-fiber area 126 of the second ply 120 may be disposed adjacent to an intersection area 128 in which the first and second fiber bundles 122 and 124 of the second ply 10 intersect each other. The non-fiber area 126 may take the form of a gap between fibers of the first and second fiber bundles 122 and 124.

As shown in FIG. 2, the first fiber bundle 122 of the second ply 120 may be stacked on the first fiber bundle 112 of the first ply 110. The first fiber bundle 122 of the second ply 120 has a substantially greater thickness than the first fiber bundle 112 of the first ply 110 (i.e., T3>T1), allowing the first fiber bundle 122 of the second ply 120 to partially overlap the non-fiber area 116 of the first ply 110.

In addition, the second fiber bundle 124 of the second ply 120 may be stacked on the second fiber bundle 114 of the first ply 110. The second fiber bundle 114 of the first ply 110 has a substantially greater thickness than the second fiber bundle 124 of the second ply 120 (i.e., T2>T4), allowing the second fiber bundle 114 of the first ply 110 to partially overlap the non-fiber area 126 of the second ply 120.

According to exemplary embodiments of the inventive concept, the second ply 120 may have a structure that is substantially the same as the structure of the first ply 110, but which is oriented or rotated by 90 degrees with respect to the first ply 110. According to other embodiments, the second ply 120 may have a structure that is substantially the same as the structure of the first ply 110, but which is oriented or rotated by 10 to 89 degrees with respect to the first ply 110.

Cracks in a circuit board can occur be various means, such as an external shock. As described above, the first and second fiber bundles of the first and second plies 110 and 120 overlap the non-fiber areas 116 and 126 of the first and second plies 110 and 120 to eliminate a crack site of the circuit board. Conversely, if the second ply 120 having the substantially same structure as the first ply 110 is directly stacked on the first ply 110 without rotation, first and second fiber bundles 112, 114, 122, and 124 do not overlap on the non-fiber areas 116 and 126. Therefore, the non-fiber areas 116 and 126 may be disposed at a crack site due to an external shock and not eliminate such crack site. Thus, in accordance with aspects of the inventive concept, the first and second fiber bundles 112, 114, 122, and 124 of the first and second plies 110 and 120 overlap the non-fiber areas 116 and 1126 to remove the crack site of the circuit board. As a result, a more reliable circuit board may be provided against a physical shock, as is shown in FIG. 3C.

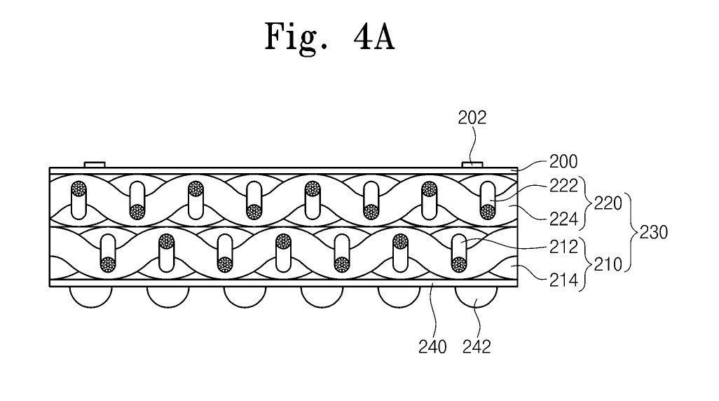

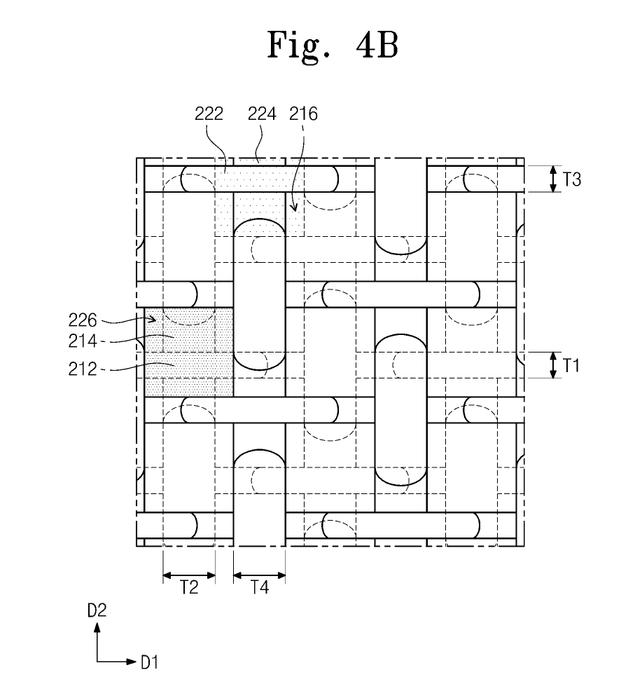

FIG. 4A is a cross-sectional view of an embodiment of a circuit board according to another aspect of the inventive concept, and FIG. 4B is a top plan view of an embodiment of a core portion of the circuit board in FIG. 4A.

Referring to FIGS. 4A and 4B, the circuit board may include a first layer 200, a second layer 240 opposite to the first layer 200, and a core portion 230 disposed between the first and second layers 200 and 240.

The core portion 230 includes a first ply 210 and a second ply 220, which may be vertically stacked.

The first ply 210 may include a first fiber bundle 212 extending in a first direction D1 and a second fiber bundle 214 extending in a second direction D2. The first and second directions D1 and D2 may be disposed at a non-zero angle to each other, such as perpendicular. The first ply 210 may include a non-fiber area 216 defined by the first and second fiber bundles 212 and 214 of the first ply 210, as shown in FIG. 4B. The non-fiber area 216 may take the form of a gap between fibers of the first and second fiber bundles 212 and 214.

Each of the first fiber bundles 212 of the first ply 210 may have a first thickness T1, and each of the second fiber bundles 214 of the first ply 210 may have a second thickness T2. According to one embodiment of the inventive concept, the second thickness may be substantially greater than the first thickness (i.e., T2>T1), as shown in FIGS. 4A and 4B. The second ply 220 may include a first fiber bundle 222 extending in a third direction and a second fiber bundle 224 extending in a fourth direction. The third and fourth directions may be perpendicular to each other. According to one embodiment of the inventive concept, the third direction may be substantially identical to the first direction D1, and the fourth direction may be substantially identical to the second direction D2, shown in FIG. 4B.

Each of the first fiber bundle 222 of the second ply 220 may have a third thickness T3, and each of the second fiber bundles 224 of the second ply 220 may have a fourth thickness T4. According to one embodiment of the inventive concept, the fourth thickness may be substantially greater than the third thickness (T4>T3).

In various embodiments, the thickness T1 of each fiber in the first fiber bundle of the first ply is substantially equal to a thickness T3 of each fiber of the first fiber bundle of the second ply, and a thickness T2 of each fiber of the second fiber bundle of the first ply is substantially equal to a thickness T4 of each fiber of the second fiber bundles of the second ply.

And the fibers of first fiber bundle 222 of the second ply 220 are disposed between adjacent fibers of the first fiber bundle 212 of the first ply 210.

The second ply 220 may include a non-fiber area 226 defined by the first and second fiber bundles 222 and 224 of the second ply 220. The non-fiber area 226 may take the form of a gap between fibers of the first and second fiber bundles 222 and 224.

As shown in FIGS. 4A and 4B, the fibers in the first fiber bundle 222 of the second ply 220 may not be directly disposed on the fibers in the first fiber bundle 212 of the first ply 210, and the first fiber bundle 222 of the second ply 220 may be oriented such that fibers in the first fiber bundle 222 of the second ply 220 are disposed between adjacent fibers in the first fiber bundle 212 of the first ply 210.

In addition, the fibers in the second fiber bundle 224 of the second ply 220 may not be directly disposed on the fibers in the second fiber bundle 214 of the first ply 210, but may rather be disposed between adjacent second fiber bundles 214 of the first ply 210.

The first layer 200, the second layer 240, a circuit pattern 202, an external terminal 242, and a core portion 230 are the same as those described with reference to FIGS. 1, 2, 3A, 3B, and 3C and will not be described in further detail.

The first fiber bundles 212 and 222 of the first and second plies 210 and 220 having the substantially same thickness are alternately and vertically stacked, and the second fiber bundles 214 and 224 of the first and second plies 210 and 220 are alternately stacked. Thus, at least part of the first and second fiber bundles 212, 214, 222, and 224 may overlap the non-fiber areas 216 and 226 of the first and second plies 210 and 220 to eliminate the above-mentioned crack state of the circuit board.

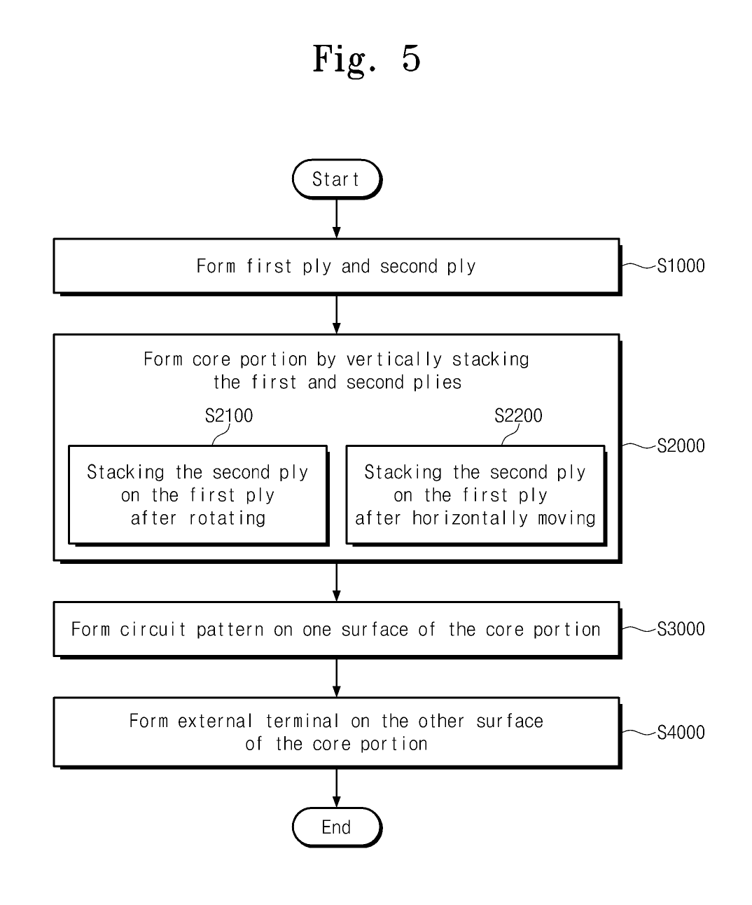

FIG. 5 is a flowchart illustrating an embodiment of a method of manufacturing a circuit board according to aspects of the inventive concept. As will be apparent in the description below, the method is described primarily with respect to the embodiment of FIGS. 1 though 3C, but generally applies to the embodiment of FIGS. 4A and 4B as well.

Referring to FIGS. 1 and 5, plies 110 and 120 may be formed. Each of the plies 110 and 120 may be formed by weaving first fiber bundles 112 and 122 extending in a first direction D1 and having a first thickness T1 and second fiber bundles 114 and 124 extending in a second direction D2 and having a second thickness T2 in a woven fabric structure. According to one embodiment of the inventive concept, the second thickness may be substantially greater than the first thickness (S1000).

A core portion 130 may be formed by vertically stacking the horizontally disposed first ply 110 and the second ply 120 (S2000).

According to one embodiment illustrated in FIGS. 3A, 3B, and 3C, after two of the plies 110 and 120 are selected, they are referred to as a first ply 110 and a second ply 120, respectively. The second ply 120 may be stacked on the first ply 110 after rotating 90 degrees. Alternatively, the second ply 120 may be stacked on the first ply 110 after rotating about 10 to about 89 degrees (S2100).

According to another embodiment illustrated in FIGS. 4A and 4B, after two of the plies 210 and 220 are selected, they are referred to as a first ply 210 and a second ply 220, respectively. The second ply 220 may be stacked on the first ply 210 after horizontally moving in one side direction, e.g., offsetting the first 210 ply with respect to the second ply 220, or vice versa. At this point, first fiber bundles 222 of the second ply 220 may move to be disposed between adjacent first fiber bundles 212 of the first ply 210 (S2200).

Returning to FIGS. 1 and 5, after a core portion 130 is formed by vertically stacking the first and second plies 110 and 120, circuit patterns 102 may be formed on one layer of the core portion 130, e.g., the first layer 100 (S3000).

Hereinafter, a process of forming the circuit pattern 102 on one layer of the core portion 130 will now be described in brief. Conventionally, after a layer of metal, such as copper, is formed on the one layer of the core portion 130 by adding a resin to the core portion 130 foamed by stacking the first and second plies 110 and 120, a structure formed by stacking the core portion 130 and the layer of metal may be pressurized and heated in a press. During the pressurizing and heating processes, the resin may be melted to bond the first and second plies 110 and 120 and the layer of metal may also be molten to be bonded to one layer of the core portion 130.

Thereafter, a via hole may be formed by means of a drilling process to penetrate the first layer 100, the second layer 140, and the core portion 130. In order to fill the via hole, a plating process may be performed to form a via 150, e.g., see FIG. 2. A circuit pattern 102 may be formed by patterning the layer of metal formed on the one layer of the core portion 130. The layer of metal may be patterned by means of a photolithography process. The circuit pattern 102 may have a stable circuit thickness by additionally performing the plating process.

External terminals 142 may be formed on the other layer of the core portion 130, such as the second layer 140. For example, each of the external terminals 142 may be a solder ball (S4000).

As described above, in the preferred embodiment the plies 110 and 120 applied to the core portion 130 are manufactured not by different processes but rather by the same process and stacked after rotating or horizontally moving. Thus, a circuit board where a crack site is eliminated may be manufactured without change of a manufacturing process.

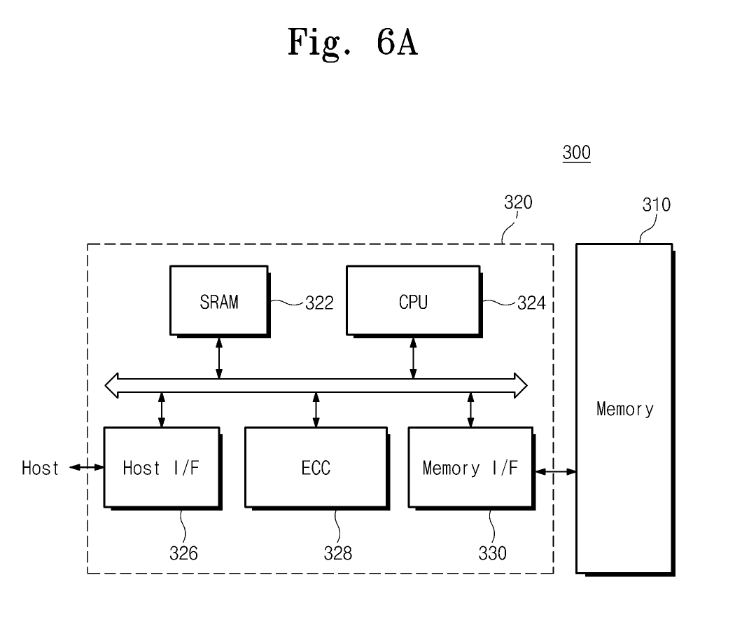

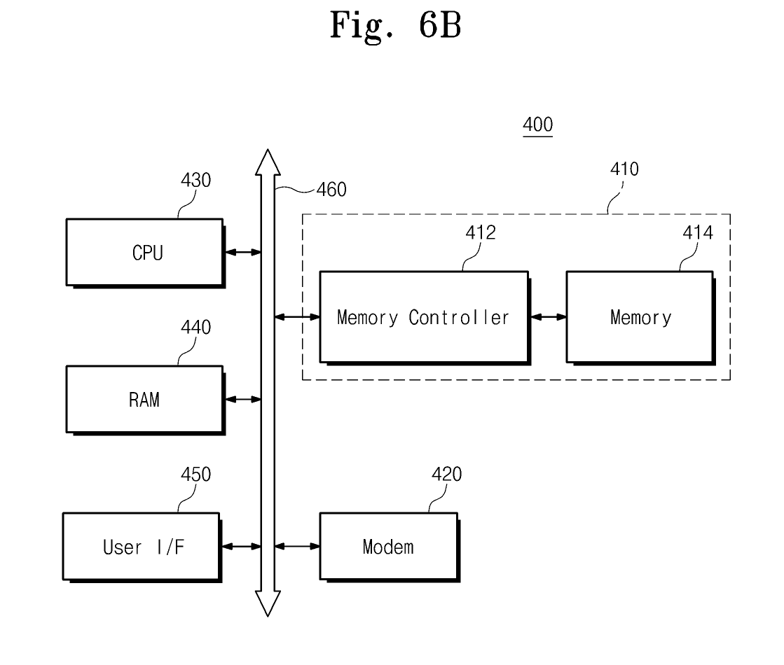

FIG. 6A is a block diagram of an embodiment of a memory card to which a memory device according to aspects of the inventive concept is applied.

Referring to FIG. 6A, a package including a circuit board according to an embodiment of the inventive concept may be applied to a memory card 300. As an example, the memory card 300 may include a memory controller 320 that controls the overall data exchange between a host and a memory 310. An SRAM 322 may be used as a working memory of a central processing unit (CPU) 324, as an example. A host interface 326 may include a data exchange protocol of a host connected to the memory card 300. An error correction code (ECC) 328 may detect and correct errors included in data read from the memory 310. The memory interface 330 interfaces with the memory 310. The CPU 324 performs the overall control operation for data exchange of the memory controller 320.

The memory 310 incorporated in the memory card 300 is applied to the package including a circuit board according to an embodiment of the inventive concept. Thus, a crack site caused by an external shock is eliminated to improve reliability against a physical shock.

FIG. 6B is a block diagram of an embodiment of a system including a memory device according to embodiments of the inventive concept.

Referring to FIG. 6B, an information processing system 400 may include a semiconductor memory device according to an embodiment of the inventive concept. For example, the information processing system 400 may include a modem 420, a central processing unit (CPU) 430, a RAM 440, and a user interface 450 which are electrically connected to a memory system 410 and a system bus 460, respectively. Data processed by the CPU 430 or external input data may be stored in the memory system 410. The memory system 410 may include a memory 412 and a memory controller 414 and may be configured with the substantially same structure as the memory card 300 described with reference to FIG. 6A. The information processing system 400 may be provided as a memory card, a solid-state disk (SSD), a camera image, and an application chipset, as examples. As an example, the memory system 410 may comprise an SSD. In this case, the information processing system 400 may stably and reliably store a large amount of data in the memory system 410.

According to embodiments of the inventive concept described above, first and second fiber bundles of a second ply are disposed to overlap at least part of a non-fiber area of a first ply. Thus, a crack site of a circuit board can be eliminated or covered to improve reliability against a physical shock applied to the circuit board.

While the inventive concept has been particularly shown and described with reference to exemplary embodiments thereof, it will be apparent to those of ordinary skill in the art that various changes in form and detail may be made therein without departing from the spirit and scope of the inventive concept, which is defined by the following claims.

1. A circuit board, comprising:
a first layer;
a second layer stacked on the first layer;
a core potion disposed between the first and second layers, the core potion comprising a plurality of plies, each ply formed of interwoven fibers,
wherein a first ply defines a first non-fiber area that is at least partially overlapped by fibers of at least one other ply.

2. The circuit board of claim 1, wherein a second ply defines a second non-fiber area that is at least partially covered by fibers of the first ply.

3. The circuit board of claim 1, wherein the plurality of plies comprises the first ply and a second ply,
the first ply comprising a first fiber bundle of the first ply having fibers extending in a first direction interwoven with a second fiber bundle of the first ply having fibers extending in a second direction; and
the second ply comprising a first fiber bundle of the second ply having fibers extending in a third direction interwoven with a second fiber bundle of the second ply having fibers extending in a second direction.

4. The circuit board of claim 3, wherein each fiber in the first fiber bundle of the first ply has a first thickness, and each fiber of the second fiber bundle of the first ply has a second thickness substantially greater than the first thickness.

5. The circuit board of claim 4, wherein each fiber of the first fiber bundle of the second ply has a third thickness, and each fiber of the second fiber bundle of the second ply has a fourth thickness substantially greater than the first thickness.

6. The circuit board of claim 5, wherein the first thickness is substantially equal to the third thickness and the second thickness is substantially equal to the fourth thickness.

7. The circuit board of claim 3, wherein:
the fibers of the first fiber bundle of the first ply are disposed at an angle in a range of about 10 to about 90 degrees to the fibers of the second fiber bundle of the second ply, and
the fibers of the second fiber bundle of the first ply are disposed at an angle in a range of about 10 to about 90 degrees to the fibers of the second fiber bundle of the second ply.

8. A circuit board comprising:
a first layer on which circuit patterns are disposed;
a second layer opposite to the first layer and on which external terminals are disposed; and
a core portion disposed between the first and second layers and including a first ply stacked on a second ply,
wherein the first ply includes a first fiber bundle extending in a first direction and a second fiber bundle extending in a second direction, with the first and second fiber bundles defining a non-fiber area of the first ply,
wherein the second ply includes first fiber bundles extending in a third direction and second fiber bundles extending in a fourth direction, and
wherein the first and second fiber bundles of the second ply overlap at least part of the non-fiber area of the first ply.

9. The circuit board of claim 8, wherein the first and second fiber bundles of the second ply defines a non-fiber area of the second ply, and
wherein the first and second fiber bundles of the first ply overlap at least part of the non-fiber area of the second ply.

10. The circuit board of claim 8, wherein each fiber in the first fiber bundle of the first ply has a first thickness, and each fiber of the second fiber bundle of the first ply has a second thickness substantially greater than the first thickness.

11. The circuit board of claim 8, wherein each fiber of the first fiber bundle of the second ply has a first thickness, and each fiber of the second fiber bundle of the second ply has a second thickness substantially greater than the first thickness.

12. The circuit board of claim 7, wherein the third direction is substantially identical to the first direction and the fourth direction is substantially identical to the second direction.

13. The circuit board of claim 12, wherein a thickness of each fiber in the first fiber bundle of the first ply is substantially smaller than a thickness of each fiber in the first fiber bundle of the second ply, and a thickness of each fiber of the second fiber bundle of the first ply is substantially greater than a thickness of each fiber of the second fiber bundle of the second ply.

14. The circuit board of claim 12, wherein a thickness of each fiber in the first fiber bundle of the first ply is substantially equal to a thickness of each fiber of the first fiber bundle of the second ply, and a thickness of each fiber of the second fiber bundle of the first ply is substantially equal to a thickness of each fiber of the second fiber bundles of the second ply, and
wherein the fibers of first fiber bundle of the second ply are disposed between adjacent fibers of the first fiber bundle of the first ply.

15. The circuit board of claim 14, wherein fibers of the second fiber bundle of the second ply are disposed between adjacent fibers of the second fiber bundle of the first ply.

16. The circuit board of claim 8, wherein the first fiber bundle of the first ply is disposed at an angle in a range of about 10 to about 90 degrees to the second fiber bundle of the second ply, and
wherein the second fiber bundle of the first ply is disposed at an angle in a range of about 10 to about 90 degrees to the second fiber bundle of the second ply.

17. The circuit board as claimed in claim 8, further comprising:
a via penetrating the first layer, the core portion, and the second layer.

18.-20. (canceled)
